(19) United States
(12) Patent Application Publication
(10) Pub. No.: US 2023/0420386 A1
(43) Pub. Date: Dec. 28, 2023

(54) SEMICONDUCTOR PACKAGING EMI SHIELDING STRUCTURE AND MANUFACTURING METHOD OF THE SAME

(71) Applicant: REALTEK SEMICONDUCTOR CORPORATION, HSINCHU (TW)

(72) Inventor: CHIA JEN CHOU, HSINCHU (TW)

(21) Appl. No.: 18/322,453

(22) Filed: May 23, 2023

(30) Foreign Application Priority Data
Jun. 24, 2022 (TW) 111123712

(51) Int. Cl. H01L 23/552; H01L 23/31; H01L 23/00; H01L 21/56

(52) U.S. Cl. CPC H01L 23/552; H01L 23/3121; H01L 2224/48247; H01L 21/561; H01L 24/48

(57) ABSTRACT

The present application discloses a semiconductor packaging structure and a manufacturing method of the same that could be commonly used for lead frame products and substrate products. The semiconductor packaging structure includes: a base layer (lead frame or organic substrate); a die, disposed on the base layer; a molding compound, filled over the base layer and surrounding the die; a shielding layer, covering the top surface and a side surface of the molding compound; and a bonding wire, having a first terminal and a second terminal, wherein the bonding wire extends the side surface of the molding compound, thus allowing the first terminal of the bonding wire to contact an inner side of the shielding layer.

### CROSS-REFERENCE TO RELATED APPLICATIONS

This application claims priority of Taiwan application No. 111123712 filed on Jun. 24, 2022, which is incorporated by reference in its entirety.

### TECHNICAL FIELD

The present application relates to an electromagnetic interference (EMI) semiconductor, particularly a semiconductor packaging structure and a manufacturing method of the same, commonly for lead frame products and substrate type products.

### BACKGROUND

A metal shield (e.g. stainless steel or copper) is formed by spraying, vaporizing or sputtering on the semiconductor package structure to avoid EMI generated by signals inside the chip from affecting the circuitry outside the chip, or to avoid EMI generated by signals outside the chip from affecting the circuitry inside the chip. Since the metal shield needs to be coupled to the ground pin of the chip, the conventional lead frame package does not have an electromagnetic shielding design, and the organic substrate needs to be exposed on the edge of the substrate through the ground wire on the substrate; however, in the case of limited space, how to connect the ground pin of the chip directly or indirectly to the metal shield is an issue that needs to be solved.

### SUMMARY OF THE INVENTION

The present application provides a semiconductor packaging structure, including: a base layer; a die, disposed on the base layer; a molding compound, filled over the base layer and surrounding the die; a shielding layer, covering the top surface and the side surface of the molding compound; and a bonding wire contacting a ground signal, wherein the bonding wire has a first terminal and a second terminal, wherein the bonding wire extends to the side surface of the molding compound, such that the first terminal of bonding wire contacts an inner side of the shielding layer.

The present application provides a method for manufacturing a semiconductor packaging structure, including: providing a base layer, including a first base layer portion, a second base layer portion and a third base layer portion respectively corresponding to a first packaging body area, a second packaging body area and a cutting channel area; disposing a first die and a second die respectively on the first base layer portion and the second base layer portion; forming a bonding wire, wherein a first terminal of the bonding wire overlaps the first base layer portion, a second terminal of the bonding wire overlaps the second base layer portion, and the bonding wire crosses the third base layer portion, in a top view; filing a molding compound over the base layer and surrounding the first die and the bonding wire; cutting the molding compound and the base layer to obtain a first portion structure corresponding to the first packaging body area and a second portion structure corresponding to the second packaging body area, wherein the bonding wire is exposed from the side surface of the first portion structure and the side surface of the second portion; and forming a shielding layer at the top surface and the side surface of the first portion structure to cover the top surface and the side surface the molding compound.

The present application addresses the issue that there is no space for the ground bonding area to extend from the organic substrate to the edge of the package to contact the shielding layer, so that the shielding layer can be applied to various package types, and can also enhance the existing shielding connection through the organic substrate.

### BRIEF DESCRIPTION OF THE DRAWINGS

Various aspects of the present application can best be understood upon reading the detailed description below and accompanying drawings. It should be noted that the various features in the drawings are not drawn to scale in accordance with standard practice in the art. In fact, the size of some features may be deliberately enlarged or reduced for the purpose of discussion.

FIG. 1 to FIG. 6 are schematic diagrams illustrating methods for manufacturing the semiconductor packaging structure of FIG. 7, according to certain embodiments of the present application.

FIG. 7 is a schematic diagram illustrating the first embodiment (the lead frame base) of the semiconductor packaging structure according to the present application.

FIG. 8 to FIG. 10 are schematic diagrams illustrating steps alternative to the embodiment of FIG. 3.

FIG. 11 is a schematic diagram illustrating the second embodiment (the organic substrate) of the semiconductor packaging structure according to the present application.

### DETAILED DESCRIPTION

At present, conformal shielding can only be used in some types of packaging structures, such as packaging structures with organic substrates, e.g., ball grid array (B GA) or land grid array (LGA) and other packaging structures. However, for other types of packaging structures, such as lead frame packaging structures, such as quad flat no leads (QFN) or advanced quad flat no leads (aQFN), conformal shielding is not available. Even in organic substrate packaging structures, there are difficulties in using conformal shielding, such as the need for sufficient space to route the ground bonding region so that it extends to the edge of the package to contact the shielding layer. The technical solution of the present application addresses these issues such that the conformal shielding can be applied to a wider range of packaging structures.

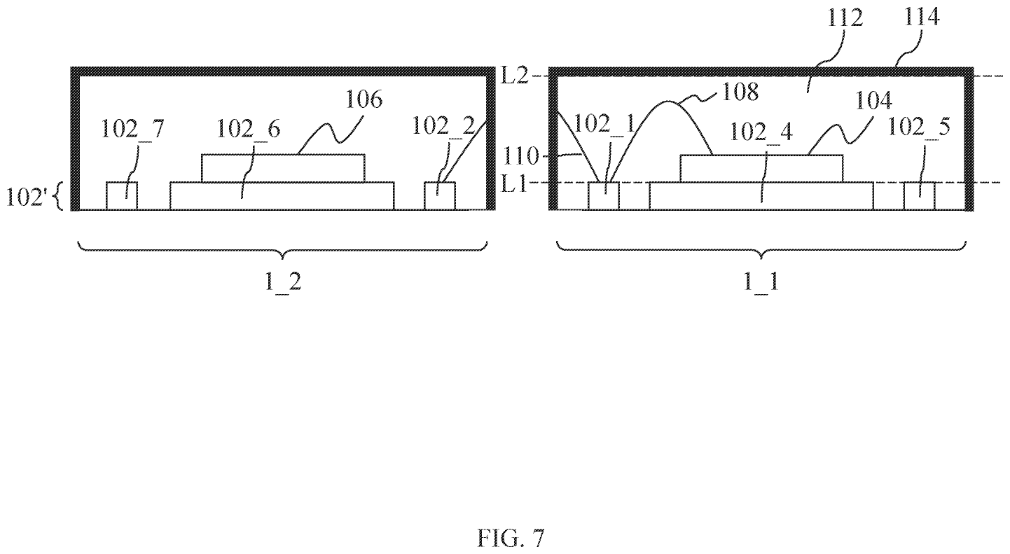

FIG. 7 is a schematic diagram illustrating the first embodiment of the semiconductor packaging structure according to the present application. The present embodiment is a QFN package structure, but the present application is not limited to it. Next, the packaging structure corresponding to the first packaging body area 1_1 (and the packaging structure on the right in FIG. 7) is illustrated. The packaging structure corresponding to the first package area 1_1 includes a base layer 102′. In the QFN package structure, the base layer 102′ co includes a plurality of lead frames 102_1, 102_4 and 102_5 that are separated from each other. A die 104 is placed on the lead frame 102_4. A molding compound 112 is filled on the base layer 102′ and surrounds the die 104, and covers the top surface and side surface of the lead frames 102_1, 102_4 and 102_5 so that only the bottom surfaces of the lead frames 102_1, 102_4 and 102_5 are exposed and are coplanar with the bottom surface of the molding compound 112, and the top surface of the molding compound 112 is facing away from the base layer 102′. In other words, the lead frames 102_1, 102_4 and 102_5 are not exposed from the top surface and side surface of the molding compound 112.

Therefore, when the shielding layer 114 is formed on the top surface and the side surface of the molded material 112 and completely covers the molded material 112, the shielding layer 114 does not directly contact the grounding bonding areas of lead frames 102_1, 102_4, and 102_5.

The packaging structure corresponding to the first packaging body area 1_1 also includes bonding wires 108 and 110, in which one terminal of the bonding wire 108 is connected to the die 104 and the other terminal of the bonding wire 108 is connected to the lead frame 102_1. One terminal of the bonding wire 110 extends to this side surface of the molding compound 112 and contacts the inner side of the shielding layer 114. In this embodiment, the location where the bonding wire 110 contacts the shielding layer 114 is between the horizontal plane L1 formed by the top surface of the base layer 102′ and the horizontal plane L2 formed by the top surface of the molded compound 112.

By means of the bonding wire 110, the inner side of the shielding layer 114 can be coupled to the ground pin in the die 104. For example, the bonding wire 110 can be coupled to the bonding wire 108 through the lead frame 102_1 (and/or other metal plated on top of the lead frame 102_1), and then coupled to the ground pin in the die 104 through the bonding wire 108.

It should be noted that the packaging structure of FIG. 7 is only for illustrative purpose, and the present application does not preclude the possibility of other bonding wires and more complex lead frame designs.

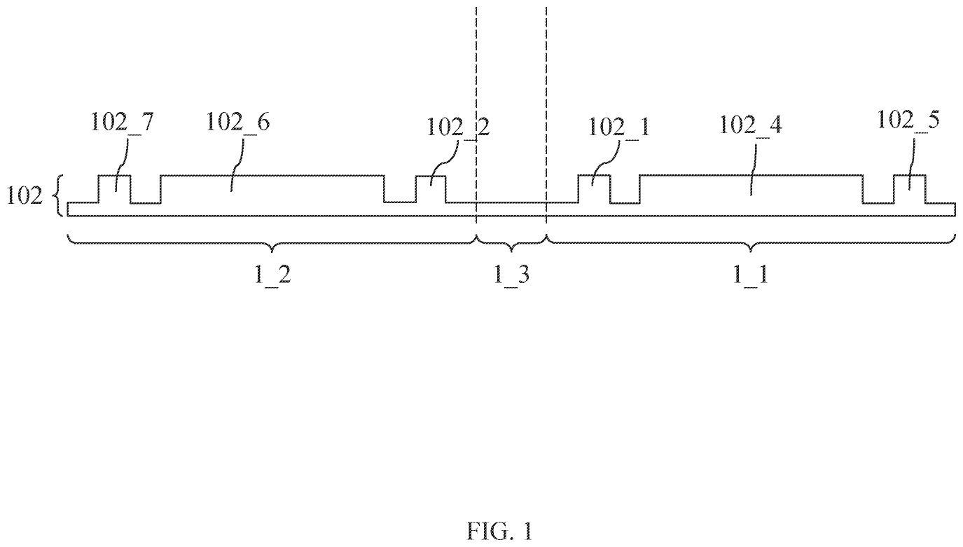

FIG. 1 to FIG. 6 are schematic diagrams illustrating embodiments of methods for manufacturing the semiconductor packaging structure of FIG. 7. In FIG. 1, the base layer 102 is provided, in which the base layer 102 includes a first base layer portion, a second base layer portion and a third base layer portion respectively corresponding to the first packaging body area 1_1, the second packaging body area 1_2 and the cutting channel area 1_3. The base layer 102 has been patterned to form lead frames 102_1, 102_2, 102_4, 102_5, 102_6 and 102_7. It should be noted that although the present embodiment only shows two packaging body areas 1_1 and 1_2 separated by the cutting channel area 1_3, the present application is not limited to it. Rather, more packaging body areas can be connected with each other.

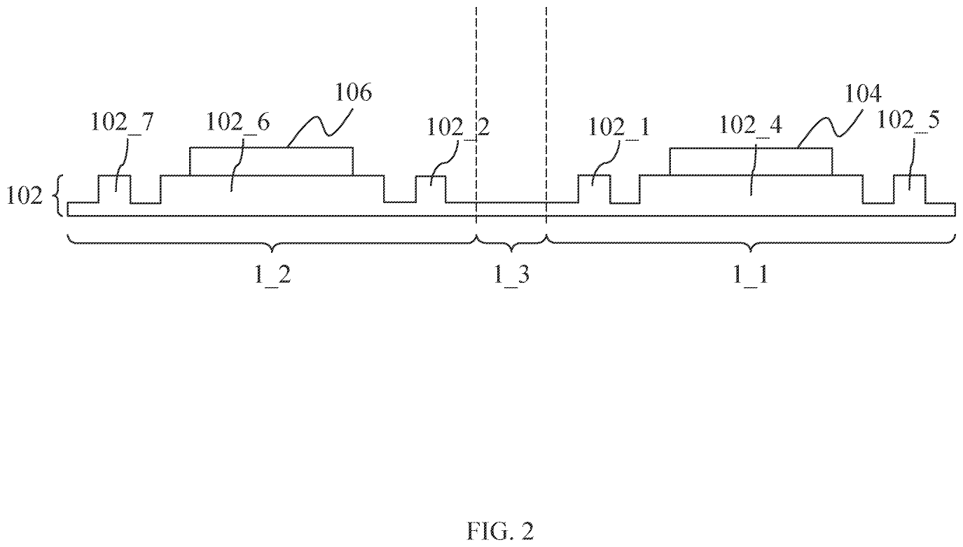

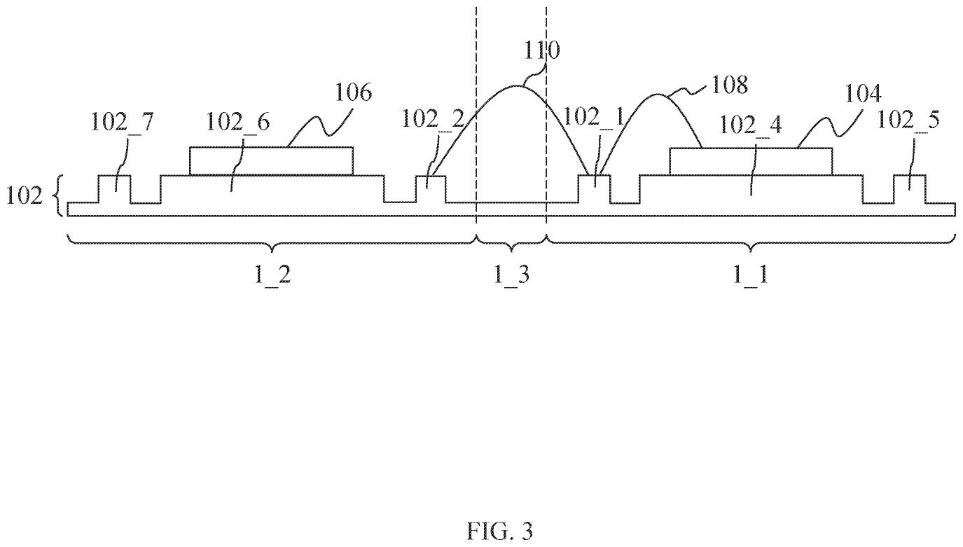

In FIG. 2, the dies 104 and 106 are respectively disposed on the lead frame 102_4 of the first base layer portion and the lead frame 102_6 of the second base layer portion. Next in FIG. 3, the bonding wires 108 and 110 are formed, in which, in a top view, one terminal of the bonding wire 110 overlaps the range of the first packaging body area 1_1 and is coupled to lead frame 102_1, whereas the other terminal of the bonding wire 110 overlaps the range of the second packaging body area 1_2 and is coupled to the lead frame 102_2, such that the bonding wire 110 crosses the cutting channel area 1_3. The bonding wire 108 completely overlaps the range of the first packaging body area 1_1, wherein one terminal of the bonding wire 108 is coupled to the die 104, and the other terminal of the bonding wire 108 is coupled to lead frame 102_1.

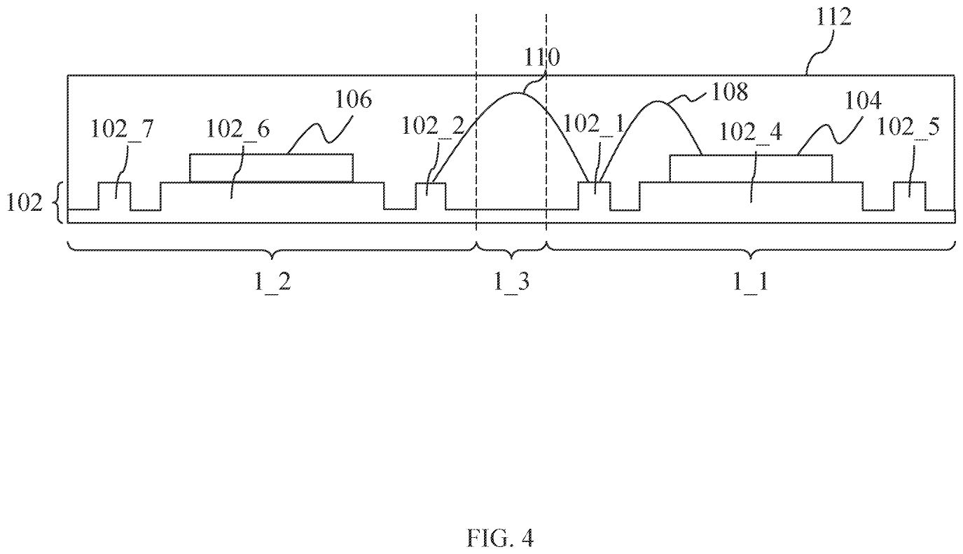

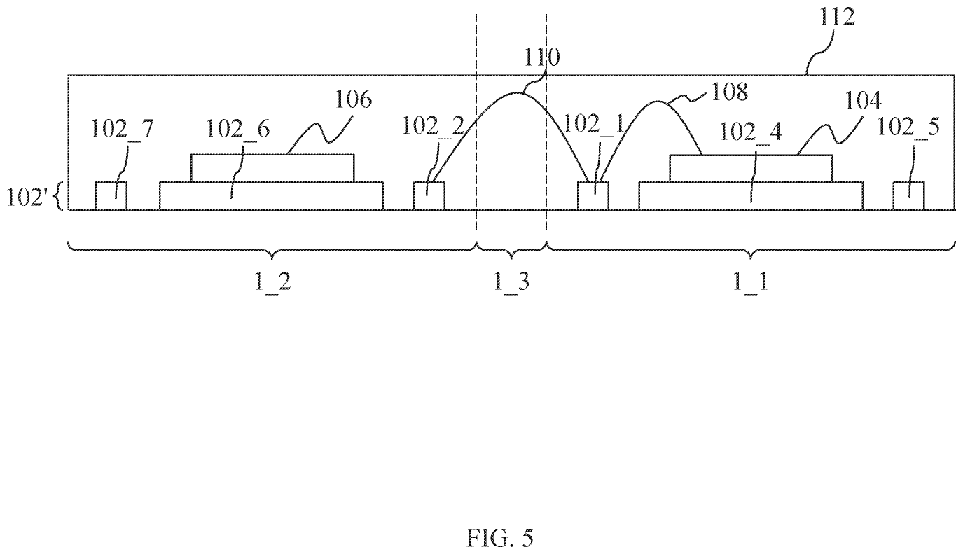

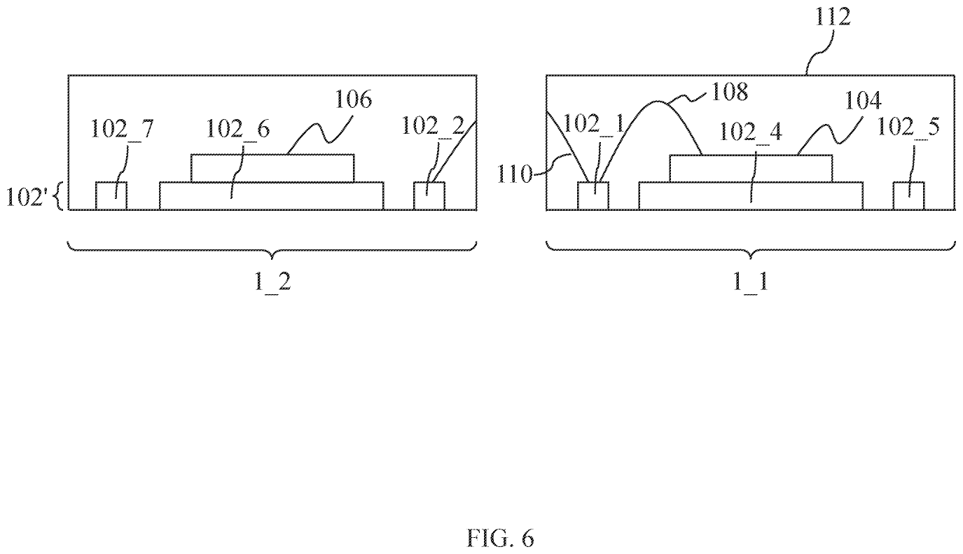

In FIG. 4, the molding compound 112 is filled on the base layer 102 and surrounding the die 104, the die 106 and the bonding wire 108, 110. Then in FIG. 5, the base layer 102 is thinned, such that the lead frames 102_1, 102_2, 102_4, 102_5, 102_6 and 102_7 are separated from each other. Then in FIG. 6, the molding compound 112 and the base layer 102 are cut, so as to obtain a first portion structure (the structure in the right of FIG. 6) corresponding to the first packaging body area 1_1 and a second portion structure (the structure in the left of FIG. 6) corresponding to the second packaging body area 1_2, wherein the bonding wire 110 is cut and exposed from the from the side surface of the first portion structure and the side surface of the second portion structure.

Lastly in FIG. 7, the shielding layer 114 is conformally formed on the top surface and the side surface of the first portion structure and the top surface and the side surface of the second portion structure, such that the molding compound 112 of the first portion structure and the second portion structure is completely shielded by the shielding layer 114.

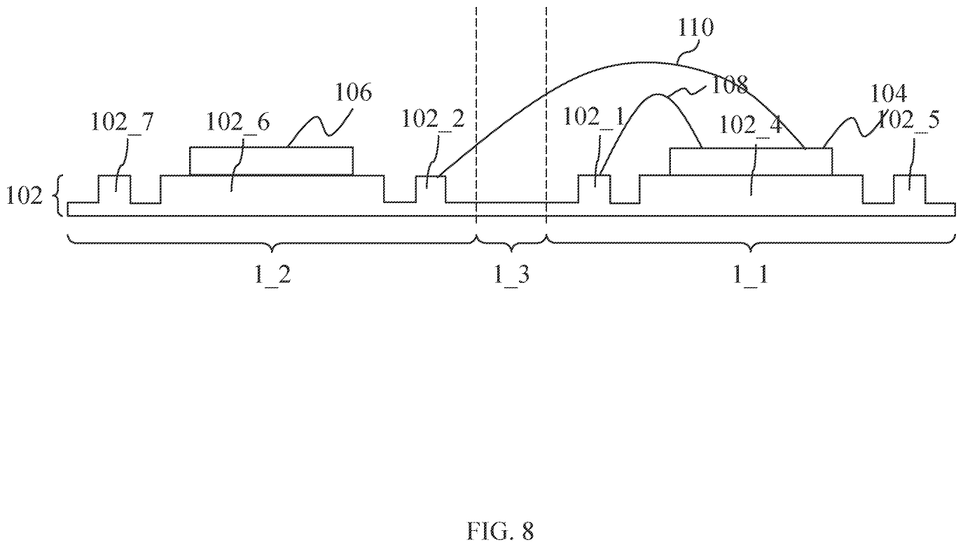

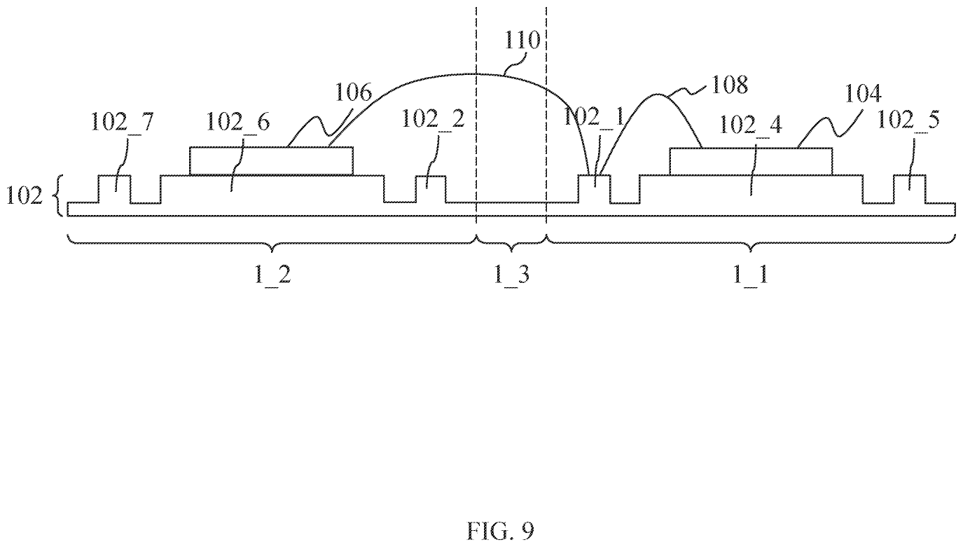

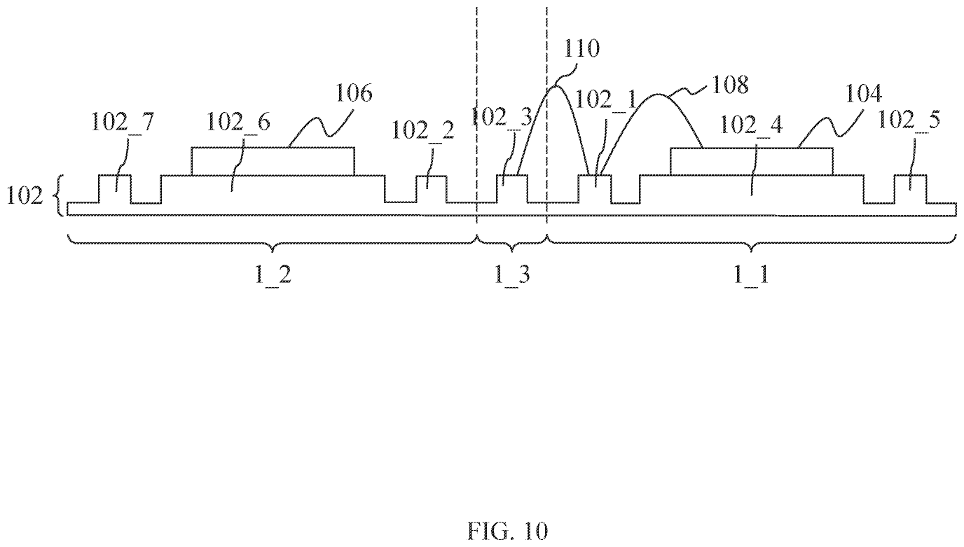

As can be seen above, in FIG. 3, the bonding wire 110 is coupled between the first packaging area 1_1 and the second packaging area 1_2 to allow the bonding wire 110 to be exposed from the cut surface of the molding compound 112 after cutting, and then when the shielding layer 114 is formed on the cut surface of the molding compound 112, the bonding wire 110 can be naturally connected to the inner side of the shielding layer 114. The way in which the bonding wire 110 can be set up to achieve the above propose is not limited to the present embodiment. In practice, as seen in the top view, it is sufficient that one terminal of the bonding wire 110 overlaps the area of the first packaging area 1_1 and the other terminal overlaps and is fixed to somewhere outside the first packaging area 1_1. For example, a terminal within the overlapping range of the bonding wire 110 and the first packaging area 1_1 can be connected to any lead frame or the die 104, as shown in FIG. 8, while the terminal outside the overlapping range of the bonding wire 110 and the first packaging area 1_1 can be connected to any lead frame or the die 106 within the range of the second packaging area 1_2, as shown in FIG. 9. It is also possible to connect a terminal outside the overlapping range of the bonding wire 110 and the first packaging area 1_1 to the additional lead frame 102_3 that is formed in the cutting channel area 1_3.

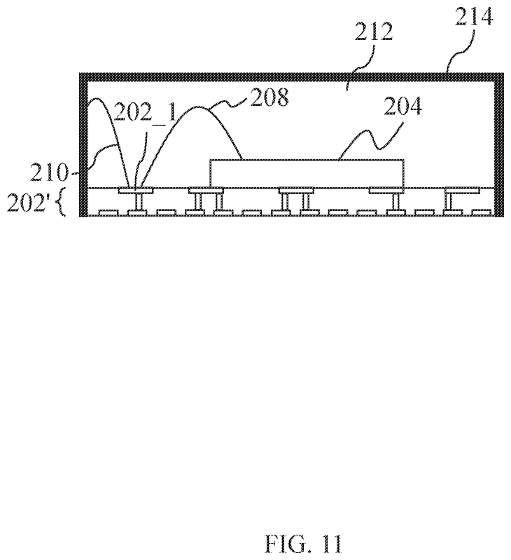

FIG. 11 is a schematic diagram illustrating the second embodiment of the semiconductor packaging structure according to the present application. This embodiment is an LGA packaging structure, but the present invention is not limited to it. The packaging structure of FIG. 11 includes a base layer 202′. In the LGA packaging structure, the base layer 202′ is an organic substrate, where the organic substrate may have multiple metal layers separated by a dielectric layer. A die 204 is placed on the organic substrate. A molding compound 212 is filled on the base layer 202′ and surrounds the die 204 and covers the top surface of the organic substrate, with the top surface of the molding compound 212 facing away from the base layer 202′. When the shielding layer 214 is formed conformally on the top and side surfaces of the molded compound 212 and the side surfaces of the organic substrate, the molded compound 212 is completely shielded and the bottom surface of the organic substrate is exposed.

The packaging structure of FIG. 11 also includes bonding wires 208 and 210, wherein one terminal of the bonding wire 208 is connected to the die 204 and the other terminal of the bonding wire 208 is connected to the bonding area 202_1 on the organic substrate. One terminal of the bonding wire 210 extends to that side surface of the molding compound 212 and contacts the inner side of the shielding layer 214. Similar to the QFN packaging embodiment in FIG. 7, the LGA packaging embodiment allows the inner side of the shielding layer 214 to be coupled to the ground pin in the die 204 through the bonding wire 210.

By means of the above embodiments, the present methods of connecting the bonding wire to the shielding layer can be applied to other kinds of packaging structures, for example, at least the embodiment of FIG. 7 can be applied to a QFN packaging structure and the embodiment of FIG. 11 can be applied to a BGA packaging structure.

What is claimed is:

1. A semiconductor packaging structure, comprising:
a base layer;
a die, disposed on the base layer;
a molding compound, filled over the base layer and surrounding the die;
a shielding layer, covering the top surface and the side surface of the molding compound; and
a bonding wire contacting a ground signal, wherein the bonding wire has a first terminal and a second terminal, wherein the bonding wire extends to the side surface of the molding compound, such that the first terminal of bonding wire contacts an inner side of the shielding layer.

2. The semiconductor packaging structure of claim 1, wherein the second terminal of the bonding wire is connected to the base layer.

3. The semiconductor packaging structure of claim 1, wherein the second terminal of the bonding wire is connected to the die.

4. The semiconductor packaging structure of claim 1, wherein the first terminal of the bonding wire is located between a horizontal plane formed by the top surface of the base layer and a horizontal plane formed by the top surface of the molding compound.

5. The semiconductor packaging structure of claim 1, wherein the base layer comprises a plurality of lead frames separated from each other.

6. The semiconductor packaging structure of claim 5, wherein the molding compound covers the top surface and the side surface of the plurality of lead frames such that only the bottom surface of the plurality of lead frames is exposed from the bottom part of the semiconductor packaging structure.

7. The semiconductor packaging structure of claim 6, wherein the shielding layer does not contact the plurality of lead frames.

8. The semiconductor packaging structure of claim 1, wherein the base layer comprises an organic substrate.

9. The semiconductor packaging structure of claim 8, wherein the bottom surface of the organic substrate is exposed from the bottom part of the semiconductor packaging structure.

10. The semiconductor packaging structure of claim 9, wherein the side surface of the organic substrate is also covered by the shielding layer.

11. A method for manufacturing a semiconductor packaging structure, comprising:
providing a base layer, comprising a first base layer portion, a second base layer portion and a third base layer portion respectively corresponding to a first packaging body area, a second packaging body area and a cutting channel area;
disposing a first die and a second die respectively on the first base layer portion and the second base layer portion;
forming a bonding wire, wherein a first terminal of the bonding wire overlaps the first base layer portion, a second terminal of the bonding wire overlaps the second base layer portion, and the bonding wire crosses the third base layer portion, in a top view;
filing a molding compound over the base layer and surrounding the first die and the bonding wire;
cutting the molding compound and the base layer to obtain a first portion structure corresponding to the first packaging body area and a second portion structure corresponding to the second packaging body area, wherein the bonding wire is exposed from the side surface of the first portion structure and the side surface of the second portion; and
forming a shielding layer at the top surface and the side surface of the first portion structure to cover the top surface and the side surface the molding compound.

12. The method of claim 11, wherein the step of forming the bonding wire comprises:
connecting the first terminal of the bonding wire to the first base layer portion.

13. The method of claim 11, wherein the step of forming the bonding wire comprises:
connecting the first terminal of the bonding wire to the first die.

14. The method of claim 11, wherein the step of forming the bonding wire comprises:
connecting the second terminal of the bonding wire to the second base layer portion.

15. The method of claim 11, wherein the step of forming the bonding wire comprises:
connecting the second terminal of the bonding wire to the second die.

16. The method of claim 11, wherein the step of forming the bonding wire comprises:
connecting the second terminal of the bonding wire to the third base layer portion.

17. The method of claim 11, wherein the base layer comprises a plurality of lead frames that are separated from each other.

18. The method of claim 17, wherein the step of filling the molding compound comprises:
forming the molding compound to cover the top surface and the side surface of the plurality of lead frames, such that only the bottom surface of the plurality of lead frames is exposed from the bottom part semiconductor packaging structure.

19. The method of claim 11, wherein the base layer comprising an organic substrate.

20. The method of claim 19, wherein the step of conformally forming the shielding layer comprises:
forming the shielding layer to cover the side surface of the organic substrate.
